(19) United States
(12) Patent Application Publication
(10) Pub. No.: US 2005/0233589 A1
(43) Pub. Date: Oct. 20, 2005

(54) Processes for removing residue from a workpiece

(76) Inventors: Brian K. Aegerter, Kalispell, MT (US); Curt T. Dundas, Kalispell, MT (US); Tom L. Ritzdorf, Big Fork, MT (US); Gary L. Curtis, Lovelang, CO (US); Michael Jolley, (US)

Correspondence Address: PERKINS COIE LLP/SEMITOOL, PO BOX 1208, SEATTLE, WA, 98111-1208, US

(21) Appl. No.: 11/151,896

(22) Filed: Jun. 14, 2005

Related U.S. Application Data
(63) Continuation of application No. 10/632,495, filed on Jul. 31, 2003.
Application No. 10/632,495 is a division of application No. 09/672,572, filed on Sep. 28, 2000, now Pat. No. 6,632,292.
Application No. 09/672,572 is a continuation-in-part of application No. 09/437,926, filed on Nov. 10, 1999, now Pat. No. 6,413,436.
Application No. 09/437,926 is a continuation of application No. PCT/US99/05674, filed on Mar. 15, 1999.
Application No. PCT/US99/05674 is a continuation-in-part of application No. 09/041,649, filed on Mar. 13, 1998, now Pat. No. 6,318,385.
Application No. PCT/US99/05674 is a continuation-in-part of application No. 09/113,435, filed on Jul. 10, 1998, now Pat. No. 6,264,752.
Application No. PCT/US99/05674 is a continuation-in-part of application No. 09/041,901, filed on Mar. 13, 1998, now Pat. No. 6,350,319.
(60) Provisional application No. 60/116,750, filed on Jan. 22, 1999.
(60) Provisional application No. 60/117,474, filed on Jan. 27, 1999.
(60) Provisional application No. 60/116,750, filed on Jan. 22, 1999.
(60) Provisional application No. 60/117,474, filed on Jan. 27, 1999.

(51) Int. Cl. H01L 21/302; B44C 1/22

(52) U.S. Cl. 438/704; 216/57

(57) ABSTRACT

In a process for removing etch residue, liquid including an acid and an oxidizer is applied to the back side and peripheral edge of a wafer. The front or device side of the wafer is left unprocessed, or may be exposed to an inert fluid such as a purge gas (e.g., nitrogen or helium), to a rinse such as deionized water, or to another processing fluid such as a more highly diluted etchant. The front side of the wafer is either left unprocessed, or is processed to a lesser degree without damage to the underlying devices, metal interconnects or semiconductor layers.

### PRIORITY CLAIM

This Application is a: Continuation of U.S. patent application Ser. No. 10/632,495 filed Jul. 31, 2003 and now pending, which is a Division of U.S. patent application Ser. No. 09/672,572 filed Sep. 28, 2000, now U.S. Pat. No. 6,632,292B1, which is a Continuation-in-Part of U.S. patent application Ser. No. 09/437,926 filed Nov. 10, 1999, now U.S. Pat. No. 6,413,436, which is a Continuation of International Application No. PCT/US99/05674, filed Mar. 15, 1999, designating the U.S. and published in English, which claims priority to U.S. patent application Ser. Nos.:
Ser. No. 09/041,649 filed Mar. 13, 1998, now U.S. Pat. No. 6,318,385;
Ser. No. 09/113,435 filed Jul. 10, 1998, now U.S. Pat. No. 6,264,752;
and Ser. No. 09/041,901 filed Mar. 13, 1998, now U.S. Pat. No. 6,350,319.

International Application No. PCT/US99/05674 and U.S. patent application Ser. No. 09/437,926 also claim priority to U.S. Provisional Patent Application Nos. 60/116,750 filed Jan. 22, 1999, and 60/117,474 filed Jan. 27, 1999. The disclosures of the following Applications are incorporated herein by reference:
U.S. patent application Ser. No. 10/632,495;
U.S. Provisional Patent Application No. 60/117,474;

International Application No. PCT/US99/05674; and
U.S. patent application Ser. No. 09/437,711, filed Nov. 10, 1999, now U.S. Pat. No. 6,423,642.

### BACKGROUND OF THE INVENTION

This invention pertains to treating a substrate such as a semiconductor wafer, e.g., a silicon wafer, so as to remove a thin film, such as a copper or other metal or oxide film, from selected regions on the wafer.

The fabrication of microelectronic circuits or components on a substrate typically involves a substantial number of processes. Many of these processes involve the deposition of a thin film on the surface of the workpiece followed by contact with a processing liquid, vapor, or gas. In these processes, contamination can occur on the back side of the workpiece and can be very detrimental to device performance.

Such contamination or residue can result from processing artifacts or from cross-contamination via fabrication tools. Such contamination can occur on the outer perimeter of a wafer as well as on its back side. It would be highly desirable if such contamination could be easily removed in a controlled manner without detrimentally affecting the front side of the workpiece.

### SUMMARY OF THE INVENTION

The present invention thus provides methods and apparatus for selectively exposing a second side of a workpiece, such as a back side of a semiconductor wafer, to an etchant solution preferably including an etchant solvent, such as an acid, and an oxidizer, to remove contamination or residue from the back side of the wafer. The present invention also provides for exposure of the peripheral edge of the workpiece, such as the bevel edge of a semiconductor wafer, to the etchant solution to remove contamination.

### BRIEF DESCRIPTION OF THE DRAWINGS

FIG. 1 is a cross-sectional view of a microelectronic workpiece housing and a rotor assembly.

FIG. 2 illustrates an edge configuration for mutually exclusive processing of the upper and lower wafer surfaces in the workpiece housing.

### DETAILED DESCRIPTION OF THE DRAWINGS

The term “film” and “contaminant” are used interchangeably herein. The term “workpiece” is not limited to semiconductor wafers, but rather refers to substrates having generally parallel planar first and second surfaces and that are relatively thin, including semiconductor wafers, ceramic wafers, and other substrates upon which microelectronic circuits or components, data storage elements or layers, and/or micromechanical elements are formed. The terms “upper” and “lower” are used herein for convenience, and other orientation are also encompassed by the invention.

Various configurations of reactors may be utilized for carrying out the selective treatment of the present invention. By way of example, the processes provided by this invention can be advantageously practiced in one of a variety of reactors illustrated and described in U.S. Pat. Nos. 6,423,642 and 6,413,436, the disclosures of which are hereby incorporated herein by reference.

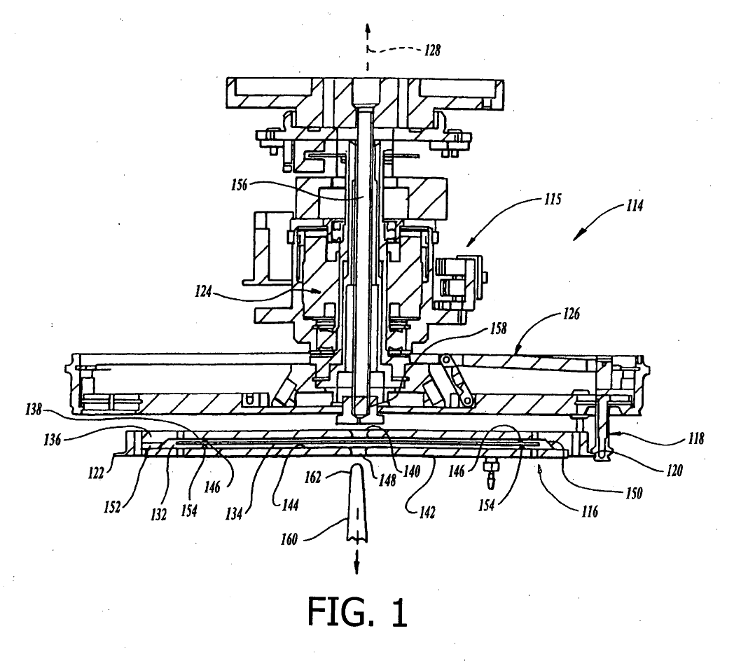

FIG. 1 is a cross-sectional view of one suitable embodiment of a reactor, shown generally at 114 and including a rotor portion 115 and a microelectronic workpiece housing 116. The rotor portion 115 includes a plurality of support members 118 that extend downwardly from the rotor portion 115 to engage the workpiece housing 116. Each of the support members 118 includes a groove 120 that is dimensioned to engage a radially extending flange 122 that extends about a peripheral region of the workpiece housing 116. Rotor portion 115 further includes a rotor motor assembly 124 that is disposed to rotate a hub portion 126, including the support members 118, about a central axis 128. Workpiece housing 116 is thus secured for co-rotation with hub portion 130 when support members 118 are engaged with flange 122. Other constructions of the rotor portion 115 and the engagement mechanism used for securement with the workpiece housing 116 may also be used.

The workpiece housing 116 of the embodiment of FIG. 1 defines a substantially closed processing chamber 132. Preferably, the substantially closed processing chamber 132 is formed in the general shape of the microelectronic workpiece 134 and closely conforms with the surfaces of the workpiece. The perimeter edge of the workpiece may be sealed, or may be in communication with fluid outlets at a perimeter edge portion 106 of the reactor.

The specific construction of FIG. 1 includes an upper chamber member 136 having an interior chamber face 138. The upper chamber member 136 includes a centrally disposed fluid inlet opening 140 in the interior chamber face 138. The specific construction also includes a lower chamber member 142 having an interior chamber face 144. The lower chamber member 142 has a centrally disposed fluid inlet opening 148 in the interior chamber face 144. The upper chamber member 136 and the lower chamber member 146 engage one another to define the processing chamber 132. The upper chamber member 136 includes sidewalls 150 that project downward from the interior chamber face 138.

One or more outlets 152 are disposed at the peripheral regions of the processing chamber 132 through the sidewalls 150 to allow fluid within the chamber 132 to exit via centrifugal force generated when the housing 116 is rotated about axis 128.

In the illustrated embodiment, the microelectronic workpiece 134 is a generally circular wafer having upper and lower planar surfaces. As such, the processing chamber 132 is generally circular in plan view and the interior chamber faces 138 and 144 are generally planar and parallel to the upper and lower planar surfaces of the workpiece 134. The spacing between the interior chamber faces 138 and 144 and the upper and lower planar surfaces of the workpiece 134 is generally quite small. Such spacing is preferably minimized to provide substantial control of the physical properties of a processing fluid flowing through the interstitial regions.

The wafer 134 is spaced from the interior chamber face 144 by a plurality of spacing members 154 extending from the interior chamber face 144. Preferably, a further set of spacing members 146 extend from the interior chamber face 138 and are aligned with the spacing members 152 to grip the wafer 134 between them.

Fluid inlet openings 140 and 148 provide communication passageways through which one or more processing fluids may enter the chamber 132 for processing the wafer surfaces. In the illustrated embodiment, processing fluids are delivered from above the wafer 134 to inlet 140 through a fluid supply tube 156 having a fluid outlet nozzle 158 disposed proximate inlet 140. Fluid supply tube 156 extends centrally through the rotor portion 115 and is preferably concentric with the axis of rotation 128. Similarly, processing fluids are delivered from below the wafer 134 to inlet 148 through a fluid supply tube 160. Fluid supply tube 160 terminates at a nozzle 162 disposed proximate inlet 148. Although nozzles 158 and 162 terminate at a position that is spaced from their respective inlets, the tubes 156 and 160 may be extended so that gaps are not present. Rather, nozzles 158 and 162 or tubes 156 and 160 may include rotating seal members that abut and seal with the respective upper and lower chamber members 136 and 146 in the regions of the inlets 140 and 148. In such instances, care should be exercised in the design of the rotating joint so as to minimize any contamination resulting from the wear of any moving component.

During processing, one or more processing fluids are individually or concurrently supplied through fluid supply tubes 156 and 160 and inlets 140 and 148 for contact with the surfaces of the workpiece 134 in the chamber 132. Preferably, the housing 116 is rotated about axis 128 by the rotor portion 115 during processing to generate a continuous flow of any fluid within the chamber 132 across the surfaces of the workpiece 134 through the action of centrifugal force. Processing fluid entering the inlet openings 140 and 148 are thus driven across the workpiece surfaces in a direction radially outward from the center of the workpiece 134 to the exterior perimeter of the workpiece 134. Rather than relying on the rotation of the workpiece, the processing fluid can also be selectively driven by pumps.

At the exterior perimeter of the workpiece 134, any spent processing fluid is directed to exit the chamber 132 through outlets 166 as a result of the centripetal acceleration. Spent processing fluids may be accumulated in a cup reservoir disposed below and/or about the workpiece housing 116.

While the back side and/or peripheral edge is being etched, the front or device side of the semiconductor wafer may be left unprocessed, or may be exposed to an inert material such as a purge gas (e.g., nitrogen or helium), to a rinse such as deionized water, or to another processing fluid such as a more highly diluted etchant. The front side of the wafer (excluding the exclusion zone) is either left unprocessed, or is processed to a lesser degree without damage to the underlying devices, metal interconnects or semiconductor layers.

The processes and apparatus may be used to remove residue remaining after dry plasma etching of the front side of a semiconductor wafer, from the backside and peripheral edge.

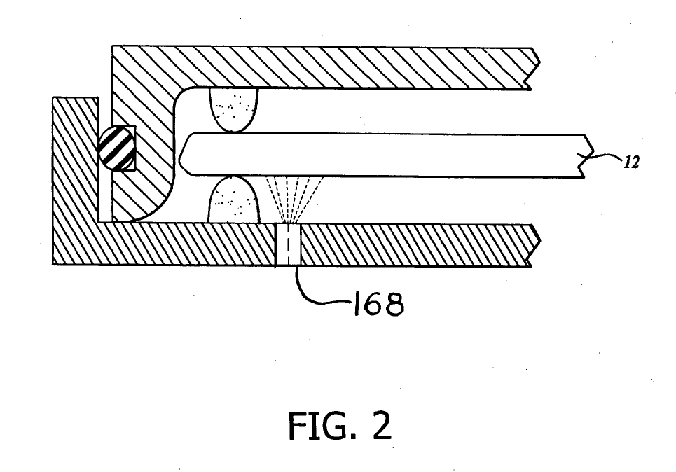

FIG. 2 illustrates a further embodiment with an inlet 168 provided for application of a fluid above the exclusion zone or at other locations through the reaction chamber wall onto the side of the wafer to be treated. The etchant is delivered by a pump to the lower chamber. An inert gas purge is preferably used as the processing fluid that is concurrently supplied and enters the upper chamber. The supply of an inert gas purge or an aqueous rinse, such as deionized water, is preferred to insure no vapor or etchant intrusion onto the majority of the first side (excluding the edge perimeter). However, the supply of fluid to the front side is not necessary, particularly for front sides coated with an exterior layer that is not vulnerable to etchant vapor, or from which a partial amount of film can be etched without a detrimental effect to the underlying layers. The etchant is caused to flow over the back side, over an outer perimeter of the silicon wafer. If treatment of the entire front side, or treatment of the back side, is desired, multiple nozzles can be used at different radial locations, or the nozzle can move inwards and outwards while applying the treatment solution.

When utilizing ozone as an oxidizer, apparatus suitably include a mixing chamber into which ozone is introduced to the solution, such as through sparging ozone gas through the solution. In addition to HF/Ozone solutions, ozone may also be included as the oxidizer, in place of H₂O₂, in the other solutions.

A still further example is removal of dry etch residue material after patterning of a wafer. Specifically, when the front side of a wafer has been etched with a dry plasma etch, a residue consisting of materials being etched or removed from the substrate surface, gas etch residue or metallization and dielectric layer residue remains on the front side of a wafer. Conventionally, this residue is removed using a solvent to which the wafer must be exposed for a long period of time, often in an excess of 60 minutes, at elevated temperatures. With the present processes, wafers may be suitably treated at ambient temperatures, e.g., 23° C., for relatively short process times of approximately one minute in length or less, using commercially available dry etch residue removal solutions such as EKC 640 and Ashland NE 89, which apparently are hydrofluoric acid or ammonium fluoride based solutions. EKC 640 is available from EKC Corporation, while Ashland NE 89 as available from the Ashland Corporation. The process entails rinsing and then exposing the front side of the wafer to the solvent, and then rinsing and drying both sides.

The present invention has been illustrated with respect to a wafer. However, it will be recognized that it has a wider range of applicability. By way of example, the present invention is applicable in the processing of disks and heads, flat panel displays, microelectronic masks, and other devices requiring effective and controlled wet processing. While the preferred embodiment of the invention has been illustrated and described, it will be appreciated that various changes can be made therein without departing from the spirit and scope of the invention.

1. A method for processing a semiconductor wafer, comprising:
dry plasma etching a front side of the semiconductor wafer, with the dry plasma etching leaving a residue on a back side of the wafer;
removing the residue from the back side of the wafer by:
spinning the wafer;
applying a liquid to the back side of the spinning wafer, with the liquid comprising de-ionized water, an acid and an oxidizer.

2. The method of claim 1 wherein the acid comprises HF and the oxidizer comprises dissolved ozone.

3. The method of claim 1 further including the step of applying the liquid to the edge of wafer, to remove residue from the edge.

4. The method of claim 1 further including the step of applying a fluid to the front side of the wafer.

5. The method of claim 4 with the fluid comprising a non-reactive liquid or gas.

6. The method of claim 1 with the liquid applied to the back side of the wafer adjacent to the edge of the wafer.

7. The method of claim 1 with the liquid applied to the back side of the wafer adjacent to a central location on the wafer.

8. The method of claim 1 wherein the liquid is sprayed onto the wafer.

9. The method of claim 1 wherein the liquid is at ambient temperature.

10. The method of claim 1 further comprising holding the wafer within a spinning processing chamber.

11. The method of claim 10 further comprising introducing the liquid into the processing chamber and draining the liquid from one or more outlets in a side wall of the processing chamber.

12. The method of claim 1 wherein the back side of the wafer is downfacing.

13. The method of claim 1 wherein the residue is removed from the back side without damaging the front side of the wafer.

14. The method of claim 5 wherein the non reactive fluid comprises a purge gas or DI.

15. The method of claim 1 with the liquid provided onto the wafer so that the liquid contacts substantially only the back surface of the wafer and the edge of the wafer.

16. The method of claim 1 further comprising applying the liquid to substantially the entire back side.

17. The method of claim 1 further comprising applying the liquid onto the workpiece via a moving nozzle.

18. A method for removing an etch residue from a back side of a workpiece, comprising:
spinning the wafer;
applying a liquid to the back side of the spinning wafer, with the liquid comprising de-ionized water, HF and dissolved ozone; and
preventing the liquid from substantially contacting the front side of the wafer.

19. A method for removing a dry plasma etch residue from a back surface and an edge of a workpiece comprising:
spinning the workpiece;
applying a liquid to the back side of the spinning workpiece, with the liquid comprising de-ionized water, hydrofluoric acid, and dissolved ozone; and
removing the liquid from the spinning workpiece via centrifugal force, without having the liquid substantially contact the front side of the workpiece.

20. The method of claim 19 with the liquid applied on to the workpiece adjacent to an edge of the workpiece.
